(19) United States
(12) Patent Application Publication
(10) Pub. No.: US 2013/0092427 A1
(43) Pub. Date: Apr. 18, 2013

(54) PRINTED CIRCUIT BOARD CAPABLE OF LIMITING ELECTROMAGNETIC INTERFERENCE

(71) Applicant: CHENG-SUNG WANG, Tu-Cheng (TW)

(72) Inventor: CHENG-SUNG WANG, Tu-Cheng (TW)

(73) Assignee: HON HAI PRECISION INDUSTRY CO., LTD., Tu-Cheng (TW)

(21) Appl. No.: 13/479,300

(22) Filed: May 24, 2012

(30) Foreign Application Priority Data
Oct. 14, 2011 (TW) 100137401

(51) Int. Cl. H05K 1/16

(52) U.S. Cl. 174/260

(57) ABSTRACT

A printed circuit board (PCB) includes a first wiring layer, a second wring layer, a power layer, a grounded layer, dielectric layers between every two active layers, a capacitor, and two through holes. A first portion of the power layer corresponding to the electromagnetic interference source is isolated from the power layer to form an independent power area. A first through hole connects the independent power area to an end of the capacitor, the second through hole connects a second portion of the power area to the other end of the capacitor. When the interference source produces interference, the interference is conducted to the independent power area and conducted to the second portion of the power area via the through holes and the capacitor.

### TECHNICAL FIELD

The present disclosure relates to printed circuit boards, particularly, to a printed circuit board capable of limiting electromagnetic interface produced by itself.

### DESCRIPTION OF RELATED ART

Many printed circuit boards (PCBs) include multiple layers. For example, a PCB 1 including four layers is shown in FIG. 5, the PCB 1 includes a first wiring layer Si, a power layer P, a grounded layer G, and a second wiring layer S2 which are arranged in sequence. Therein, there is a dielectric layer B placed between each two adjacent layers of the first wiring layer S1, the power layer P, the grounded layer G, and the second wiring layer S2. The power layer P is used to provide power to the first wiring layer S1 and to the second wiring layer S2, the grounded layer G is used to provide a ground connection to the first wiring layer S1 and to the second wiring layer S2. The first wiring layer S1 may include a time schedule controller used to produce timed signals on a schedule for controlling a processor or a storage controller or the like, in an electronic device equipped with the PCB 1. The timed signals would be converted to frequency domain signals, however, the frequency domain signals may be interference frequency to the PCB 1, therefore, the time schedule controller is a source of interference on the PCB 1.

A touch input device and an electronic device with the touch input device can overcome the described limitations.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross section view of a printed circuit board capable of limiting electromagnetic interference, in accordance with an exemplary embodiment.

FIG. 2 is a top view of a power layer of the printed circuit board of FIG. 1, in accordance with an exemplary embodiment.

FIG. 3 is top view of a grounded layer of the printed circuit board of FIG. 1, in accordance with an exemplary embodiment.

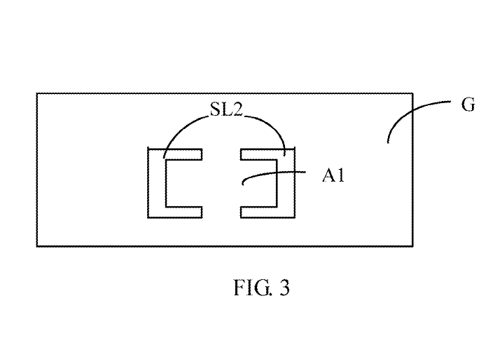

FIG. 4 is a top view of a grounded film attached on the printed circuit board of FIG. 1, in accordance with an exemplary embodiment.

FIG. 5 is a cross section view of a printed circuit board in related art.

### DETAILED DESCRIPTION

Embodiments of the present disclosure will be described, with reference to the accompanying drawings.

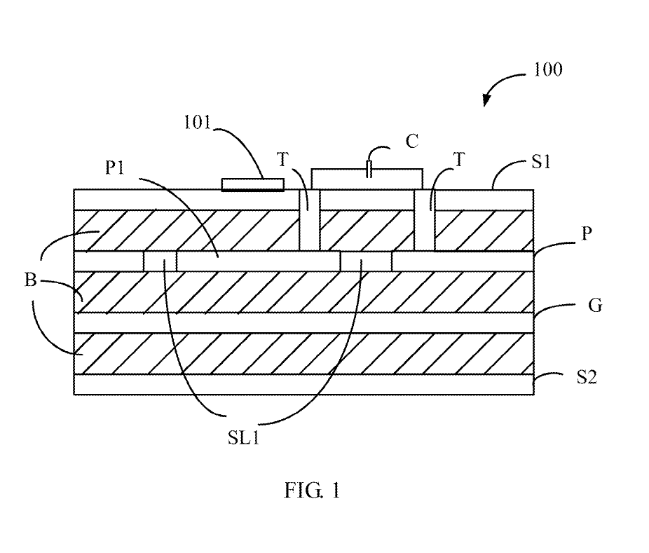

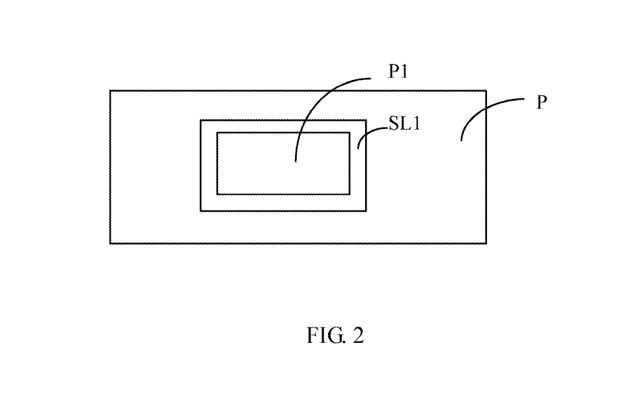

Referring to FIGS. 1 and 2 together, a printed circuit board (PCB) 100 capable of limiting electromagnetic interference produced by itself is shown. The PCB 100 includes a first wiring layer S1, a power layer P, a grounded layer G, and a second wiring layer S2. The PCB 100 also includes dielectric layers B which are placed between each adjacent two layers of the first wiring layer S1, the power layer P, the grounded layer G, and the second wiring layer S2. The power layer P is used to provide power to the first wiring layer S1 and to the second wiring layer S2, the grounded layer G is used to provide a ground connection to the first wiring layer S1 and to the second wiring layer S2.

The first wiring layer S1 includes an interference source 101 which produces electromagnetic interference, in the embodiment, the interference source 101 is a time schedule controller. A first portion of the power layer P corresponding to the interference source 101 is isolated from the power layer P to form an independent power area P1. In the embodiment, the position of the independent power area P1 is corresponding to the interference source 101, and a size of the independent power area P1 is substantially similar to the footprint of the interference source 101. As shown in FIG. 2, there is an annular clearance slot SL1 located between the independent power area P1 and a second portion of the power area P to separate the independent power area P1 from the power area P. The independent power area P1 is used to provide power to the interference source 101. In the embodiment, as shown in FIG. 2, the independent power area P1 is rectangular, the shape of the independent power area P1 may be in any appropriate shape, namely, the independent power area P1 is governed or is not governed by the shape of the interference source 10.

In the embodiment, the PCB 100 also includes at least two through holes T and at least one capacitor C1. As shown in FIG. 1, the number of the through holes T is two and the number of the capacitor C1 is one, and the two through holes T pass through the first wiring layer S1 and through the dielectric substrates B located between the first wiring layer S1 and the power layer P. One of the through holes T is connected to the independent power area P1 and an end of the capacitor C1, the other one of the through holes T is connected to the second portion of the power area P and the other end of the capacitor C1. In the embodiment, the inner wall of each through hole T is coated with insulating material, and the two through holes T are filled with conductive material. Therefore, the two through holes T and the capacitor C1 constitute a conductive path and the independent power area P1 is electrically connected to the second portion of the power area P via the through holes T and the capacitor C1. In another embodiment, the number of the through holes T and the capacitor C1 can be suitable for any particular layout, for example, the number of the through holes T may be four, and the number of the at least one capacitor C1 may be two, to create two conductive paths.

Therefore, when the interference source 101 produces electromagnetic interference, the electromagnetic interference is conducted to the independent power area P1 and then conducted to the second portion of the power area P. Then the electromagnetic interference produced by the interference source 101 is significantly reduced.

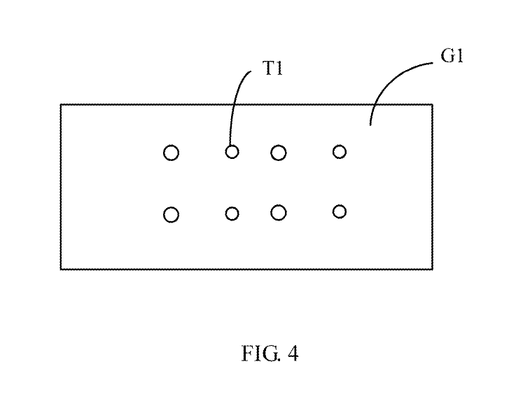

Referring to FIG. 4, in the embodiment, the grounded layer G with an unclosed annular slot SL2, and the position of an area A1 surrounded by the unclosed annular slot SL2 is corresponding to the interference source 101, namely, the position of an area A1 is immediately below the interference source 101. The area A1 reinforces the isolation between the interference source 101 and all the other elements of the PCB 100.

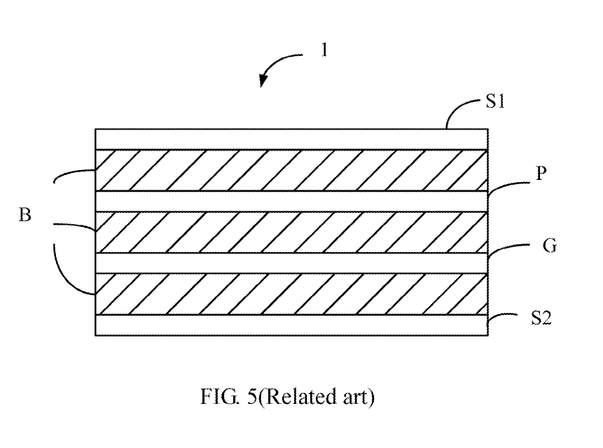

Referring to FIG. 5, in the embodiment, the PCB 100 also includes grounded films G1, attached on the bottom surface of the first wiring layer S1 and the bottom surface of the second wiring layer S2. In the embodiment, the two grounded films G1 include several through holes T1. The through holes T1 of the grounded film G1 attached on the first wiring layer S1 pass through the power layer P and the dielectric substrates B to connect the grounded film G1 to the grounded layer G. The through holes T1 of the grounded film G1 attached on the second wiring layer S2 pass through the second wiring layer S2 and the dielectric substrates B, and connect the grounded film G1 to the grounded film G1. In the embodiment, the structure of the through holes T1 is similar to the through hole T, namely, the inner wall of each through hole T1 is coated with insulating material, and each through hole T1 are filled with conductive material.

Therefore, the two grounded film G1 are electrically connected to the grounded layer G, which effectively enlarges the area of the grounded layer G and further dampens and reduces the electromagnetic interference.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A printed circuit board (PCB) comprising;
a first wiring layer comprising an interference source which produces electromagnetic interference;
a power layer, wherein, a first portion of the power layer corresponding to the interference source is isolated from the power layer to form an independent power area, the independent power area is configured to provide power to the interference source;
a second wiring layer;
a grounded layer;
a plurality of dielectric layers respectively placed between each adjacent two layers of the first wiring layer, the power layer, the grounded layer, and the second wiring layer;
a capacitor;
a first through hole, connected between the independent power area and an end of the capacitor; and
a second through hole, connected between a second portion of the power area and the other end of the capacitor;
wherein, the inner wall of each through hole is coated with insulating material, and the two through holes are filled with conductive material, the independent power area is electrically connected to the second portion of the power area via the through holes and the capacitor, when the interference source produces the electromagnetic interference, the electromagnetic interference is conducted to the independent power area and then to the second portion of the power area via the through holes and the capacitor.

2. The PCB according to claim 1, wherein the position of the independent power area is corresponding to the interference source, and a size of the independent power area is substantially similar to a footprint of the interference source.

3. The PCB according to claim 1, wherein he PCB further comprises an annular clearance slot located between the independent power area and the second portion of the power area to separate the independent power area from the power area.

4. The PCB according to claim 1, wherein the grounded layer comprises an unclosed annular slot, and the position an area surround by the unclosed annular slot is corresponding to the interference source.

5. The PCB according to claim 1, wherein the power layer is configured to provide power to the first wiring layer and the second wiring layer, the grounded layer is configured to provide ground potential to the first wiring layer and the second wiring layer.

6. The PCB according to claim 1, further comprising two grounded films, wherein the two grounded films are attached on a bottom surface of the first wiring layer and the second wiring layer.

7. The PCB according to claim 6, wherein the two grounded films both comprise a plurality of third through holes, the plurality of third through holes of one of the grounded films are attached on the first wiring layer and pass through the power layer and the dielectric substrates to connect the grounded film to the grounded layer, the plurality of third through holes of the other of the grounded films are attached on the second wiring layer and pass through the second wiring layer and the dielectric substrates to connect the grounded film to the grounded film.

8. The PCB according to claim 7, wherein the inner wall of each third through hole is coated with insulating material and is filled with conductive material.
